(19) United States
(12) Patent Application Publication
(10) Pub. No.: US 2024/0128149 A1
(43) Pub. Date: Apr. 18, 2024

(54) COOLING INTERFACE REGION FOR A SEMICONDUCTOR DIE PACKAGE

(71) Applicant: Taiwan Semiconductor Manufacturing Company, Ltd., Hsinchu (TW)

(72) Inventors: Cheng-Chieh HSIEH, Tainan (TW); Wei-Kong SHENG, Miaoli County (TW); Ke-Han SHEN, Chiayi City (TW); Yu-Jen LIEN, Tainan City (TW)

(21) Appl. No.: 18/190,540

(22) Filed: Mar. 27, 2023

Related U.S. Application Data
(60) Provisional application No. 63/379,398, filed on Oct. 13, 2022.

(51) Int. Cl. H01L 23/367; H01L 23/00; H01L 23/31

(52) U.S. Cl. CPC H01L 23/3675; H01L 23/3128; H01L 24/13; H01L 24/43; H01L 2224/32225; H01L 2224/73265; H01L 2924/1436

(57) ABSTRACT

Some implementations described herein include systems and techniques for fabricating a semiconductor die package that includes a cooling interface region formed in surface of an integrated circuit die. The cooling interface region, which includes a combination of channel regions and pillar structures, may be directly exposed to a fluid above and/or around the semiconductor die package.

### CROSS-REFERENCE TO RELATED APPLICATION

This patent application claims priority to Provisional Patent Application No. 63/379,398 filed on Oct. 13, 2022, and entitled “Cooling Interface Region for a Semiconductor Die Package”. The disclosure of the prior application is considered part of and is incorporated by reference into this patent application.

### BACKGROUND

A semiconductor die package may include one or more integrated circuit (IC) dies, or chips, from a semiconductor wafer, such as a system-on-chip (SoC) IC die, a dynamic random access memory (DRAM) IC die, or a high bandwidth memory (HBM) IC die. The semiconductor die package may include an interposer that provides an interface between the one or more IC dies and a substrate. The semiconductor die package may further include one or more connection structures to provide electrical connectivity for signaling between the one or more IC dies, the interposer, and the substrate. Additionally and/or alternatively, IC dies may be vertically stacked and/or directly bonded without the use of an interposer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2D are diagrams of example implementations of a semiconductor die package including an example cooling interface region described herein.

FIG. 3 is a diagram of example implementations of pillars included in the cooling interface region described herein.

FIGS. 4A-4J are diagrams of an example manufacturing process used to fabricate the cooling interface region described herein.

FIG. 5 is a diagram of example components of one or more devices of FIG. 1 described herein.

FIG. 6 is a flowchart of an example process associated with manufacturing a semiconductor package including the cooling interface region described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a semiconductor die package may include an integrated circuit (IC) die such as a dynamic random access memory (DRAM) IC die, a system-on-chip (SoC) IC die, and/or another type of IC die. Heat generated by the IC die during a duty cycle may damage the IC die if the semiconductor die package is not able to dissipate the heat at a rate that enables a temperature of the IC die to satisfy a threshold (e.g., a junction temperature threshold).

To dissipate the heat, the semiconductor die package may include a layered stack including a thermal interface material, a heat spreader component, and/or a lid component, among other examples. A top surface of the layered stack (e.g., the lid component, among other examples) may have an approximately planar contour. Due to the approximately planar contour, a fluid flowing over the semiconductor package may be dominated by a laminar flow, thereby reducing a rate of convective heat transfer from the semiconductor package. Additionally, the layered stack may increase a thickness of the semiconductor die package to consume space in a computing system including the semiconductor die package. Additionally, multiple manufacturing steps used to fabricate the layered stack may consume resources of a fabrication facility (e.g., manufacturing tools, materials, and/or computing resources, among other examples) and reduce the efficiency of the fabrication facility relative to another fabrication facility that fabricates the semiconductor die package without the layered stack.

Some implementations described herein include systems and techniques for fabricating a semiconductor die package that includes a cooling interface region formed in surface of an integrated circuit die. The cooling interface region, which includes a combination of channel regions and pillar structures, may be directly exposed to a fluid above and/or around the semiconductor die package.

In this way, the cooling interface region causes a turbulent flow of the fluid to increase a rate of convective heat transfer from the semiconductor die package relative to a semiconductor package not including the cooling interface region. Additionally, a thickness of the semiconductor die package may be reduced relative to another semiconductor die package including a thermal interface material, a heat spreader component, and/or a lid component. The reduced thickness of the semiconductor die package may conserve space in a computing system, may enable the size of the computing system to be reduced, and/or may enable the semiconductor die package to be used in small form factor applications, such as mobile computing and Internet of things (IoT). Additionally, the semiconductor die package including the cooling interface region may increase the efficiency of the fabrication facility relative to another fabrication facility that fabricates the semiconductor die package including the thermal interface material, the heat spreader component, and/or the lid component.

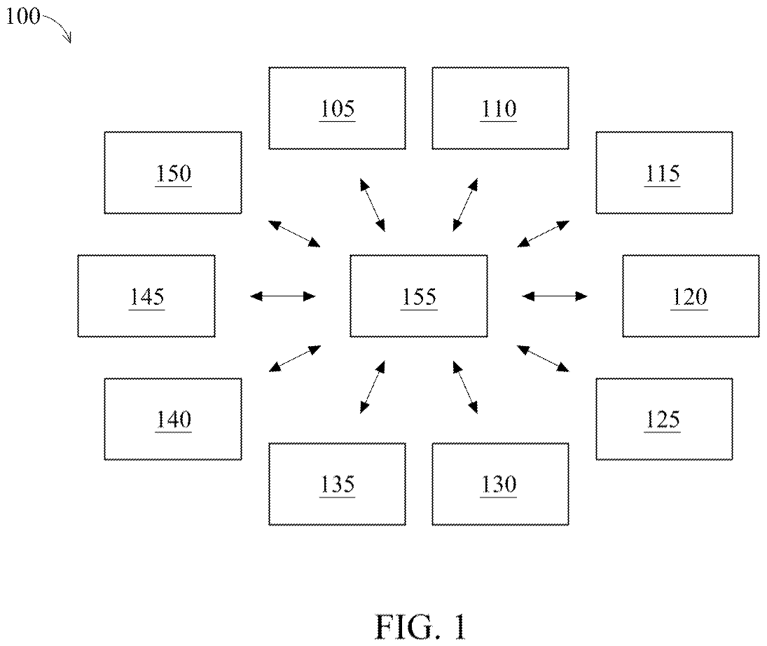

FIG. 1 is a diagram of an example environment 100 in which systems and/or methods described herein may be implemented. As shown in FIG. 1, environment 100 may include a plurality of semiconductor processing tool sets 105-150 and a transport tool set 155. The plurality of semiconductor processing tool sets 105-150 may include a redistribution layer (RDL) tool set 105, a planarization tool set 110, a connection tool set 115, an automated test equipment (ATE) tool set 120, a singulation tool set 125, a die-attach tool set 130, an encapsulation tool set 135, a printed circuit board (PCB) tool set 140, a surface mount (SMT) tool set 145, and a finished goods tool set 150. The semiconductor processing tool sets 105-150 of example environment 100 may be included in one or more facilities, such as a semiconductor clean or semi-clean room, a semiconductor foundry, a semiconductor processing facility, an outsourced assembly and test (OSAT) facility, and/or a manufacturing facility, among other examples.

In some implementations, the semiconductor processing tool sets 105-150, and operations performed by the semiconductor processing tool sets 105-150, are distributed across multiple facilities. Additionally, or alternatively, one or more of the semiconductor processing tool sets 105-150 may be subdivided across the multiple facilities. Sequences of operations performed by the semiconductor processing tool sets 105-150 may vary based on a type of the semiconductor package or a state of completion of the semiconductor package.

One or more of the semiconductor processing tool sets 105-150 may perform a combination of operations to assemble a semiconductor package (e.g., attach one or more IC dies to a substrate, where the substrate provides an external connectivity to a computing device, among other examples). Additionally, or alternatively, one or more of the semiconductor processing tool sets 105-150 may perform a combination of operations to ensure a quality and/or a reliability of the semiconductor package (e.g., test and sort the one or more IC dies, and/or the semiconductor package, at various stages of manufacturing).

The semiconductor package may correspond to a type of semiconductor package. For example, the semiconductor package may correspond to a flipchip (FC) type of semiconductor package, a ball grid array (BGA) type of semiconductor package, a multi-chip package (MCP) type of semiconductor package, or a chip scale package (CSP) type of semiconductor package. Additionally, or alternatively, the semiconductor package may correspond to a plastic leadless chip carrier (PLCC) type of semiconductor package, a system-in-package (SIP) type of semiconductor package, a ceramic leadless chip carrier (CLCC) type of semiconductor package, or a thin small outline package (TSOP) type of semiconductor package, among other examples.

The RDL tool set 105 includes one or more tools capable of forming one or more layers and patterns of materials (e.g., dielectric layers, conductive redistribution layers, and/or vertical connection access structures (vias), among other examples) on a semiconductor substrate (e.g., a semiconductor wafer, among other examples). The RDL tool set 105 may include a combination of one or more photolithography tools (e.g., a photolithography exposure tool, a photoresist dispense tool, a photoresist develop tool, or a photoresist ashing tool, among other examples), a combination of one or more etch tools (e.g., a plasma-based etched tool, a dry-etch tool, or a wet-etch tool, tool among other examples), and one or more deposition tools (e.g., a chemical vapor deposition (CVD) tool, a physical vapor deposition (PVD) tool, an atomic layer deposition (ALD) tool, or a plating tool, among other examples). In some implementations, the example environment 100 includes a plurality of types of such tools as part of RDL tool set 105.

The planarization tool set 110 includes one or more tools that are capable of polishing or planarizing various layers of the semiconductor substrate (e.g., the semiconductor wafer). The planarization tool set 110 may also include tools capable of thinning the semiconductor substrate. The planarization tool set 110 may include a chemical mechanical planarization (CMP) tool or a lapping tool, among other examples. In some implementations, the example environment 100 includes a plurality of types of such tools as part of the planarization tool set 110.

The connection tool set 115 includes one or more tools that are capable of forming connection structures (e.g., electrically-conductive structures) as part of the semiconductor package. The connection structures formed by the connection tool set 115 may include a wire, a stud, a pillar, a bump, or a solder ball, among other examples. The connection structures formed by the connection tool set 115 may include materials such as a gold (Au) material, a copper (Cu) material, a silver (Ag) material, a nickel (Ni) material, a tin (Sn) material, or a palladium (Pd) material, among other examples. The connection tool set 115 may include a bumping tool, a wirebond tool, or a plating tool, among other examples. In some implementations, the example environment 100 includes a plurality of types of such tools as part of the connection tool set 115.

The ATE tool set 120 includes one or more tools that are capable of testing a quality and a reliability of the one or more IC dies and/or the semiconductor package (e.g., the one or more IC dies after encapsulation). The ATE tool set 120 may perform wafer testing operations, known good die (KGD) testing operations, semiconductor package testing operations, or system-level (e.g., a circuit board populated with one or more semiconductor packages and/or one or more IC dies) testing operations, among other examples. The ATE tool set 120 may include a parametric tester tool, a speed tester tool, and/or a burn-in tool, among other examples. Additionally, or alternatively, the ATE tool set 120 may include a prober tool, probe card tooling, test interface tooling, test socket tooling, a test handler tool, burn-in board tooling, and/or a burn-in board loader/unloader tool, among other examples. In some implementations, the example environment 100 includes a plurality of types of such tools as part of the ATE tool set 120.

The singulation tool set 125 includes one or more tools that are capable of singulating (e.g., separating, removing) the one or more IC dies or the semiconductor package from a carrier. For example, the singulation tool set 125 may include a dicing tool, a sawing tool, or a laser tool that cuts the one or more IC dies from the semiconductor substrate. Additionally, or alternatively, the singulation tool set 125 may include a trim-and-form tool that excises the semiconductor package from a leadframe. Additionally, or alternatively, the singulation tool set 125 may include a router tool or a laser tool that removes the semiconductor package from a strip or a panel of an organic substrate material, among other examples. In some implementations, the example environment 100 includes a plurality of types of such tools as part of the singulation tool set 125.

The die-attach tool set 130 includes one or more tools that are capable of attaching the one or more IC dies to the interposer, the leadframe, and/or the strip of the organic substrate material, among other examples. The die-attach tool set 130 may include a pick-and-place tool, a taping tool, a reflow tool (e.g., a furnace), a soldering tool, or an epoxy dispense tool, among other examples. In some implementations, the example environment 100 includes a plurality of types of such tools as part of the die-attach tool set 130.

The encapsulation tool set 135 includes one or more tools that are capable of encapsulating the one or more IC dies (e.g., the one or more IC dies attached to the interposer, the leadframe, or the strip of organic substrate material). For example, the encapsulation tool set 135 may include a molding tool that encapsulates the one or more IC dies in a plastic molding compound. Additionally, or alternatively, the encapsulation tool set 135 may include a dispense tool that dispenses an epoxy polymer underfill material between the one or more IC dies and an underlying surface (e.g., the interposer or the strip of organic substrate material, among other examples). In some implementations, the example environment 100 includes a plurality of types of such tools as part of the encapsulation tool set 135.

The PCB tool set 140 incudes one or more tools that are capable of forming a PCB having one or more layers of electrically-conductive traces. The PCB tool set 140 may form a type of PCB, such as a single layer PCB, a multi-layer PCB, or a high density connection (HDI) PCB, among other examples. In some implementations, the PCB tool set 140 forms the interposer and/or the substrate using one or more layers of a buildup film material and/or fiberglass reinforced epoxy material. The PCB tool set 140 may include a laminating tool, a plating tool, a photoengraving tool, a laser cutting tool, a pick-and-place tool, an etching tool, a dispense tool, a bonding tool, and/or a curing tool (e.g., a furnace) among other examples. In some implementations, the example environment 100 includes a plurality of types of such tools as part of the PCB tool set 140.

The SMT tool set 145 includes one or more tools that are capable of mounting the semiconductor package to a circuit board (e.g., a central processing unit (CPU) PCB, a memory module PCB, an automotive circuit board, and/or a display system board, among other examples). The SMT tool set 145 may include a stencil tool, a solder paste printing tool, a pick-and-place tool, a reflow tool (e.g., a furnace), and/or an inspection tool, among other examples. In some implementations, the example environment 100 includes a plurality of types of such tools as part of the SMT tool set 145.

The finished goods tool set 150 includes one or more tools that are capable of preparing a final product including the semiconductor package for shipment to a customer. The finished goods tool set 150 may include a tape-and-reel tool, a pick-and-place tool, a carrier tray stacking tool, a boxing tool, a drop-testing tool, a carousel tool, a controlled-environment storage tool, and/or a sealing tool, among other examples. In some implementations, the example environment 100 includes a plurality of types of such tools as part of the finished goods tool set 150.

The transport tool set 155 includes one or more tools that are capable of transporting work-in-process (WIP) between the semiconductor processing tools 105-150. The transport tool set 155 may be configured to accommodate one or more transport carriers such a wafer transport carrier (e.g., a wafer cassette or a front opening unified pod (FOUP), among other examples), a die carrier transport carrier (e.g., a film frame, among other examples), and/or a package transport carrier (e.g., a joint electron device engineering (JEDEC) tray or a carrier tape reel, among other examples). The transport tool set 155 may also be configured to transfer and/or combine WIP amongst transport carriers. The transport tool set 155 may include a pick-and-place tool, a conveyor tool, a robot arm tool, an overhead hoist transport (OHT) tool, an automated materially handling system (AMHS) tool, and/or another type of tool. In some implementations, the example environment 100 includes a plurality of types of such tools as part of the transport tool set 155.

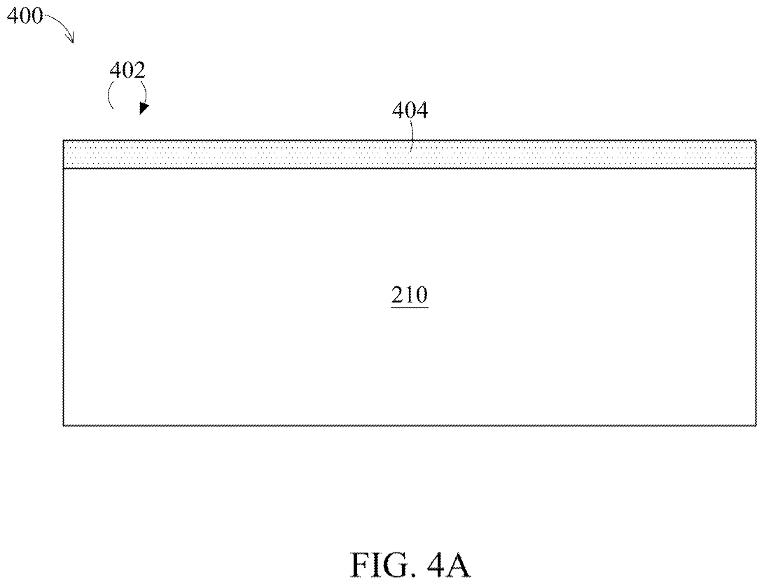

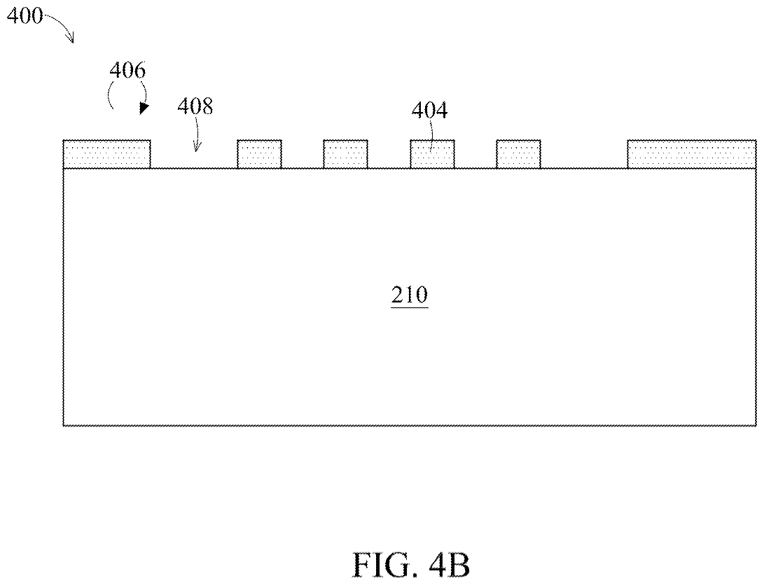

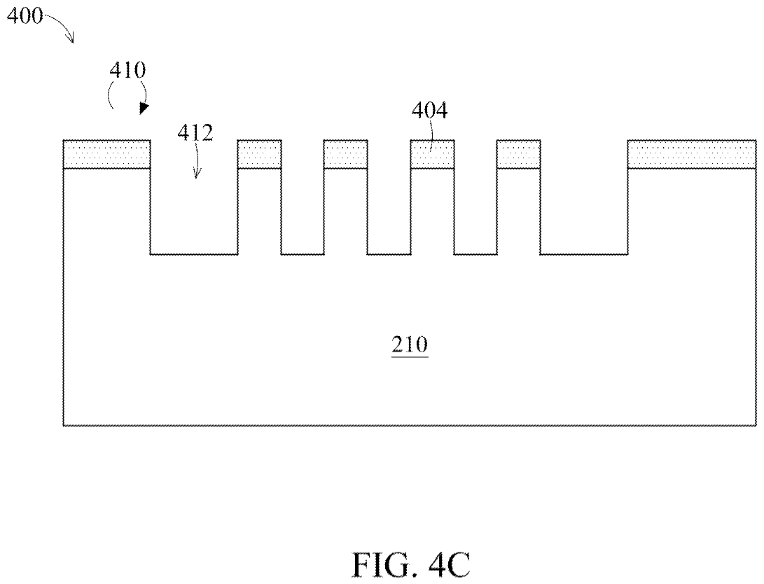

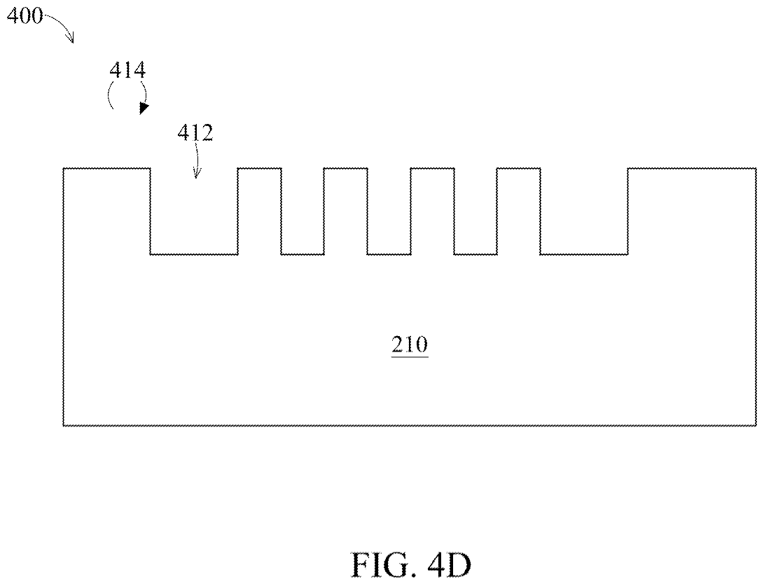

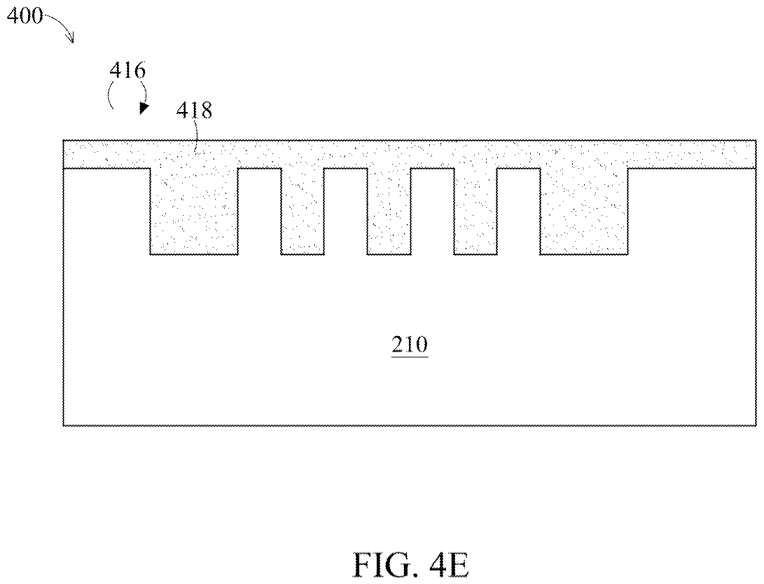

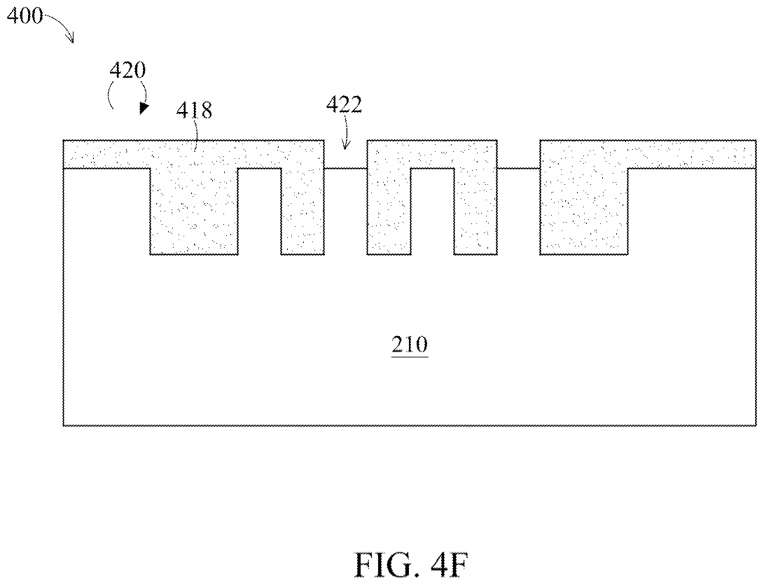

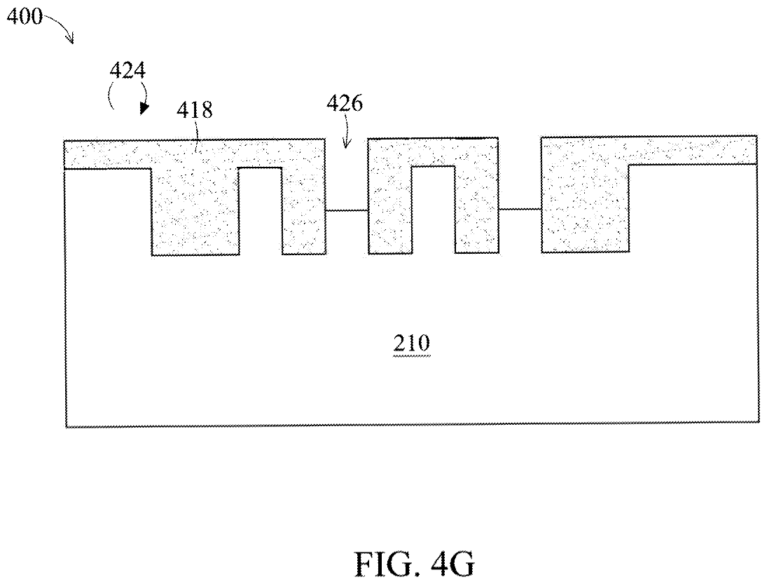

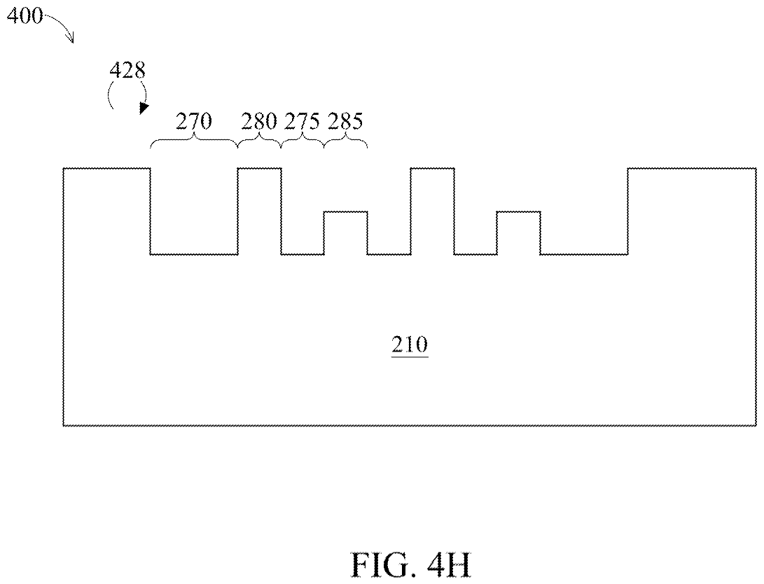

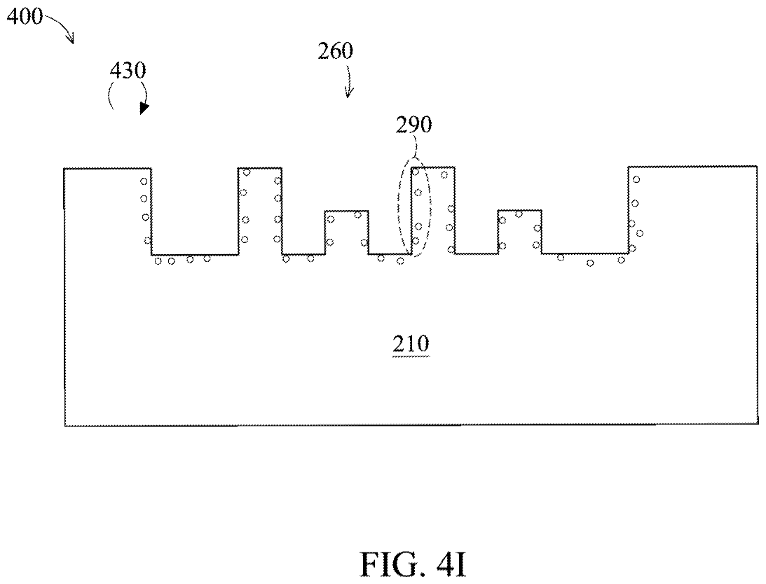

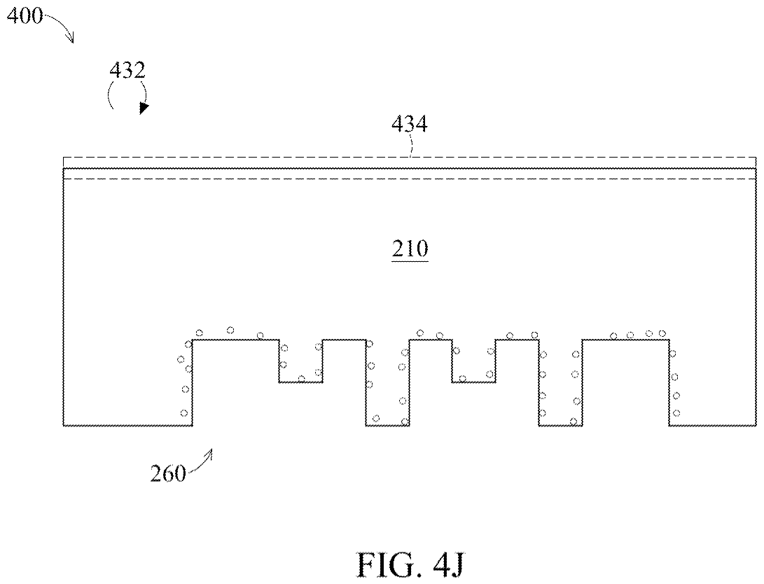

One or more of the semiconductor processing tool sets 105-150 may perform one or more manufacturing operations. For example, and as described in greater detail in connection with FIGS. 4A-4J and elsewhere herein, the one or more processing tool sets 105-150 may perform a series of manufacturing operations to form a cooling interface region of a semiconductor die package. The series of manufacturing operations includes forming, in an integrated circuit die, a first set of pillar structures along a first horizontal axis, where the first set of pillar structures includes, in a top-down view of the integrated circuit die, a first pillar structure and a second pillar structure separated by a channel region, where the first pillar structure extends to a first height above a bottom of the channel region, and where the second pillar structure extends to a second height above the bottom of the channel region. The series of manufacturing operations includes forming, in the integrated circuit die, a second set of pillar structures along a second horizontal axis that is approximately parallel to the first horizontal axis, where the second set of pillar structures includes, in the top-down view of the integrated circuit die, a third pillar structure and a fourth pillar structure separated by the channel region, where the third pillar structure extends to the first height above the bottom of the channel region, and where the fourth pillar structure extends to the second height above the bottom of the channel region.

The number and arrangement of tool sets shown in FIG. 1 are provided as one or more examples. In practice, there may be additional tool sets, different tool sets, or differently arranged tool sets than those shown in FIG. 1. Furthermore, two or more tool sets shown in FIG. 1 may be implemented within a single tool set, or a tool set shown in FIG. 1 may be implemented as multiple, distributed tool sets. Additionally, or alternatively, one or more tool sets of environment 100 may perform one or more functions described as being performed by another tool set of environment 100.

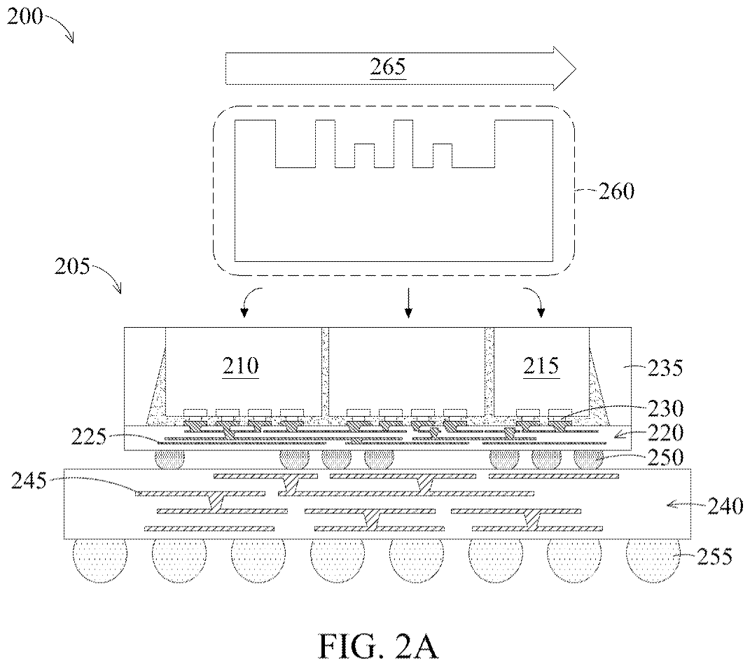

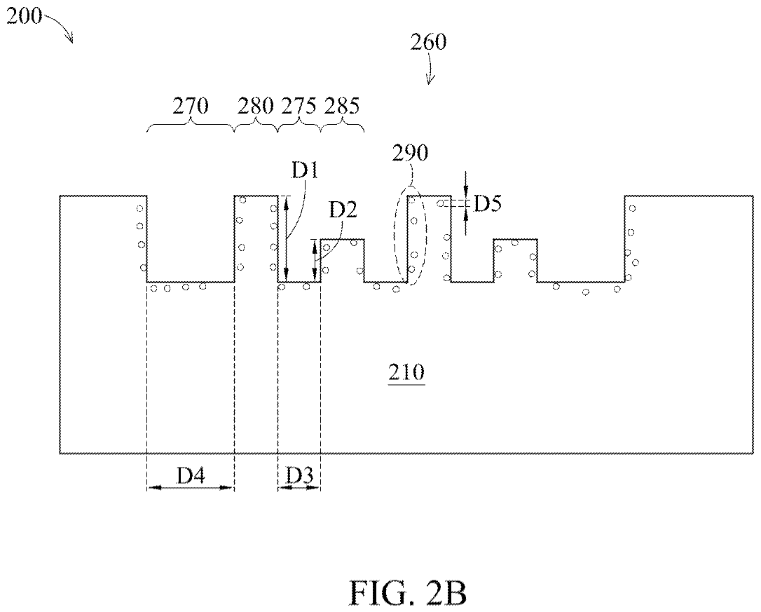

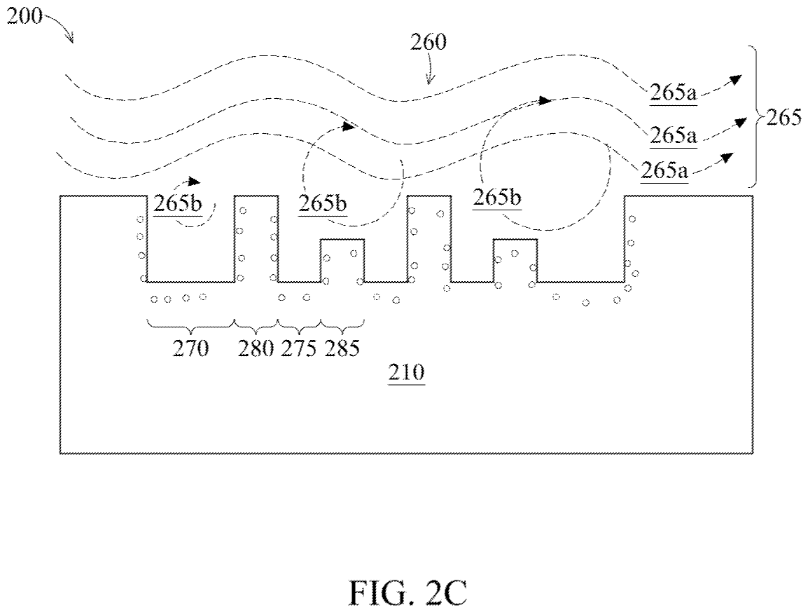

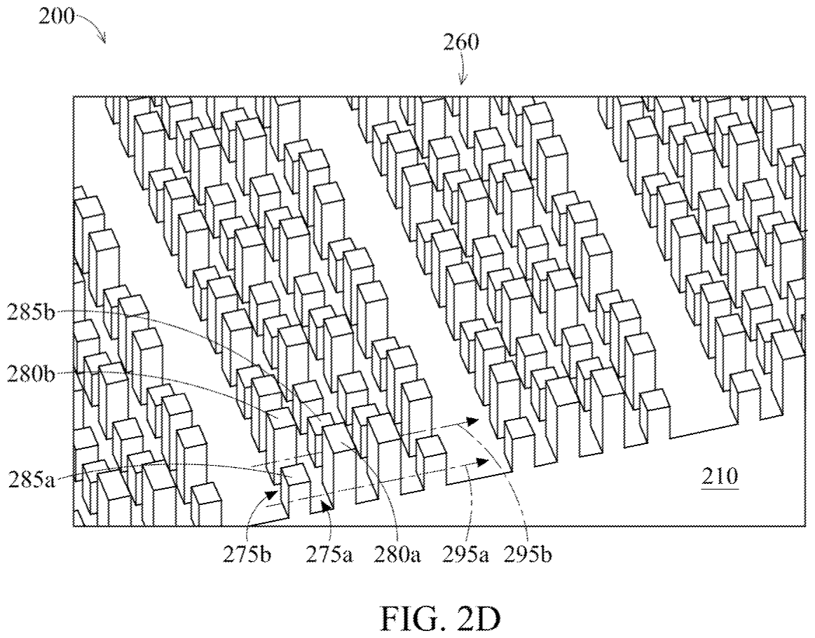

FIGS. 2A-2D are diagrams of example implementations 200 of a semiconductor die package 205 including an example cooling interface region described herein. In some implementations, the semiconductor die package 205 corresponds to a high-performance computing (HPC) semiconductor package.

As shown in the side view of FIG. 2A, the semiconductor die package 205 may include one or more IC dies (e.g., a system-on-chip (SoC) IC die 210 and/or a dynamic random access memory (DRAM) IC die 215, among other examples). The semiconductor die package 205 may include an interposer 220 (e.g., an intermediate substrate) having one or more layers of electrically-conductive traces 225. The interposer 220 may include one or more layers of a dielectric material, a polymer material, a ceramic material, and/or a silicon material, among other examples. In some implementations, the interposer 220 corresponds to a PCB including layers of a glass-reinforced epoxy laminate material and/or a pre-preg material (e.g., a composite fiber/resin/epoxy material), among other examples. Additionally, or alternatively, one or more layers of the interposer 220 may include a buildup film material.

The electrically-conductive traces 225 may include one or more materials such as a gold (Au) material, a copper (Cu) material, a silver (Ag) material, a nickel (Ni) material, a tin (Sn) material, or a palladium (Pd) material, among other examples. In some implementations, the interposer 220 includes one or more conductive vertical access connection structures (vias) that connect one or more layers of the electrically-conductive traces 225.

As shown in FIG. 2, the SoC IC die 210 and the DRAM IC die 215 are connected (e.g., mounted) to the interposer 220 using a plurality of connection structures 230. The connection structures 230 may include one or more combinations of a stud, a pillar, a bump, or a solder ball, among other examples. The connection structures 230 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

The connection structures 230 may connect lands (e.g., pads) on bottom surfaces of the SoC IC die 210 and the DRAM IC die 215 to lands on a top surface of the interposer 220. In some implementations, the connection structures 230 may include one or more electrical connections for signaling (e.g., corresponding lands of the SoC IC die 210, the DRAM IC die 215, and the interposer 220 are electrically connected to respective circuitry and/or traces of the SoC IC die 210, the DRAM IC die 215, and the interposer 220).

In some implementations, the connection structures 230 may include one or more mechanical connections for attachment purposes and/or spacing purposes (e.g., corresponding lands of the SoC IC die 210, the DRAM IC die 215, and the interposer 220 are not electrically connected to respective circuitry and/or traces of the SoC IC die 210, the DRAM IC die 215, and the interposer 220). In some implementations, one or more of the connection structures 230 may function both electrically and mechanically.

A mold compound 235 may encapsulate one or more portions of the semiconductor die package 205, including portions of the SoC IC die 210 and/or the DRAM IC die 215. The mold compound 235 (e.g., a plastic mold compound, among other examples) may protect the SoC IC die 210 and/or the DRAM IC die 215 from damage during manufacturing of the semiconductor die package 205 and/or during field use of the semiconductor die package 205.

The semiconductor die package 205 may include a substrate 240 having one or more layers of electrically-conductive traces 245. The substrate 240 may include one or more layers of a dielectric material, such as a ceramic material or a silicon material. In some implementations, the substrate 240 corresponds to a PCB including layers of a glass-reinforced epoxy laminate material and/or a pre-preg material (e.g., a composite fiber/resin/epoxy material), among other examples. Additionally, or alternatively, one or more layers of the substrate 240 may include a buildup film material.

The electrically-conductive traces 245 may include one or more materials such as a gold (Au) material, a copper (Cu) material, a silver (Ag) material, a nickel (Ni) material, a tin (Sn) material, or a palladium (Pd) material, among other examples. In some implementations, the substrate 240 includes one or more conductive vertical access connection structures (vias) that connect one or more layers of the electrically-conductive traces 245.

As shown in FIG. 2A, the interposer 220 is connected (e.g., mounted) to the substrate 240 using a plurality of connection structures 250. The connection structures 250 may include one or more combinations of a stud, a pillar, a bump, or a solder ball, among other examples. In some implementations, the connection structures 250 correspond to controlled collapse chip connection (C4) connection structures. The connection structures 250 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

The connection structures 250 may connect lands (e.g., pads) on a bottom surface of the interposer 220 to lands on a top surface of the substrate 240. In some implementations, the connection structures 250 may include one or more electrical connections for signaling (e.g., corresponding lands of the interposer 220 and the substrate 240 are electrically connected to respective circuitry and/or traces of the interposer 220 and the substrate 240). In some implementations, the connection structures 250 may include or more mechanical connections for attachment purposes and/or spacing purposes (e.g., corresponding lands of the interposer 220 and the substrate 240 are not electrically connected to respective circuitry and/or traces of the interposer 220 and the substrate 240). In some implementations, one or more of the connection structures 250 may function both electrically and mechanically.

The semiconductor die package 205 may include a plurality of connection structures 255 connected to lands (e.g., pads) on a bottom surface of the substrate 240. The connection structures 255 may include one or more combinations of a stud, a pillar, a bump, or a solder ball, among other examples. The connection structures 255 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free). In some implementations, the connection structures 255 correspond to C4 connection structures.

The connection structures 255 may be used to attach the semiconductor die package 205 (e.g., the substrate 240) to a circuit board (not shown) using a surface mount (SMT) process. In some implementations, the connection structures 255 may provide an electrical connection for signaling (e.g., corresponding lands of the substrate 240 and the circuit board may be electrically connected to respective circuitry and/or traces of the substrate 240 and the circuit board). In some implementations, the connection structures 255 may provide a mechanical connection to the circuit board for attachment purposes and/or spacing purposes (e.g., corresponding lands of the substrate 240 and the circuit board may not be electrically connected to respective circuitry and/or traces of the substrate 240 and the circuit board). In some implementations, one or more of the connection structures 255 may provide both mechanical and electrical connections.

The semiconductor die package 205 may include a thermal control network having thermal conduction mechanisms. As an example, and some implementations, the connections structures 230, the connection structures 250, and the connection structures 255 may conduct heat from the SoC IC die 210 and/or the DRAM IC die 215 for eventual dissipation from the semiconductor die package 205.

As further shown in FIG. 2A, one or more IC dies of the semiconductor die package 205 (e.g., the SoC IC die 210, the DRAM IC die 215, and/or another IC die) may include a cooling interface region 260. The cooling interface region 260 may be configured to be exposed to a fluid 265 to transfer heat from the semiconductor die package 205 using a convection heat transfer mechanism. The cooling interface region 260 may transfer the heat without an intervening thermal interface material, an intervening heat spreader component, and/or an intervening lid component.

As described in connection with FIGS. 2B-2D and elsewhere herein, the cooling interface region 260 may include a combination of pillar structures and/or channel regions. The combination of pillar structures and/or channel regions may correspond to a heterogeneous structure (e.g., a combination of different constituents and/or dissimilar components).

The cooling interface region 260 causes a turbulent flow of the fluid 265 to increase a rate of convective heat transfer from the semiconductor die package 205 relative to another semiconductor package not including the cooling interface region 260. Moreover, the use of pillar structures may increase the amount of surface area that may be contacted by the flow of the fluid 265, which increases the amount of surface area through which heat may be transferred away from the semiconductor die package 205. Additionally, or alternatively, a thickness of the semiconductor die package 205 may be reduced relative to the other semiconductor die package including a thermal interface material, a heat spreader component, and/or a lid component, thereby saving space in a computing system. Additionally, or alternatively, the semiconductor die package 205 including the cooling interface region 260 may increase the efficiency of the fabrication facility relative to another fabrication facility that fabricates the other semiconductor die package including the thermal interface material, the heat spreader component, and/or the lid component.

FIG. 2B shows a side view including details of the cooling interface region 260. As shown in FIG. 2B, the cooling interface region 260 may be included in a backside surface of an IC die (e.g., a backside surface of the SoC IC die 210, among other examples). The cooling interface region 260 may include one or more channel regions, including a channel region 270 and a channel region 275, among other examples. The cooling interface region 260 may further include a row of pillar structures, including a pillar structure 280 and a pillar structure 285, among other examples. In some implementations, and as shown in FIG. 2B, the channel region 275 is between (e.g., separates) the pillar structure 280 and the pillar structure 285. The channel region 275 may be adjacent to a side of the pillar structure 280 and the channel region 270 may be adjacent to an opposite side of the pillar structure 280. In some implementations, the channel region 270, the channel region 275, the pillar structure 280, and/or the pillar structure 285 include a porous surface 290. The porous surface 290 may enable the fluid 265 to flow into a portion of the surface of an IC die by capillary action. A pillar structure or channel region that includes the porous surface 290 provides an increased amount of surface area in which the fluid 265 may contact the IC die, which enable increased transfer of heat away from the IC die.

Features of the cooling interface region 260 may include one or more dimensional properties. For example, the pillar structure 280 may extend approximately vertically to a height D1 above a bottom of the channel region 270 and the pillar structure 285 may extend approximately vertically to a height D2 above the bottom of the channel region 270. In some implementations, the height D1 is greater relative to the height D2 (e.g., the height D2 is lesser relative to the height D1). As an example, a ratio of the height D2 to the height D1 (e.g., D2:D1) may be greater than approximately 1.2, where D2 is included in a range of approximately 0.3 millimeters to approximately 3.5 millimeters.

If the ratio D2:D1 is less than approximately 1.2, vapor bubbles may not detach from the pillar structure 280 and/or the pillar structure 285 during convection heat transfer from the cooling interface region 260, thereby lessening an effectiveness of the cooling interface region as a convection heat transfer component. Additionally, or alternatively, if the height D2 is less than approximately 0.3 millimeters, a surface area of the cooling interface region 260 may not be sufficiently increased to improve a rate of the convection heat transfer. Additionally, or alternatively, if the height D2 is greater than approximately 3.5 millimeters, manufacturing costs of the cooling interface region 260 may increase. However, other values and ranges for the ratio D2:D1, and the height D2, are within the scope of the present disclosure.

The channel region 275 may include a width D3 and the channel region 270 may include a width D4. In some implementations, the width D4 is greater relative to the width D3 (e.g., the width D4 is lesser relative to the width D3). As an example, a ratio of the width D4 to the width D3 (e.g., D4:D3) may be greater than approximately 3:2, where the width D4 is greater than approximately 10 microns.

If the ratio D4:D3 is less than approximately 3:2, surfaces of the cooling interface region 260 may become dry (e.g., “dry out”) to reduce an effectiveness of the cooling interface region 260 as a convection heat transfer component. Additionally, or alternatively, if the width D4 is less than approximately 10 microns, a flow drag of a passive fluid system (e.g., a non-pumped system supplying the fluid 265) may be increased to decrease an effectiveness of the convection heat transfer. However, other values and ranges for the ratio D4:D3, and the width D4, are within the scope of the present disclosure.

Additionally, or alternatively, a width D5 of a pore included in the porous surface 290 may be included in a range of greater than 0 microns to less than approximately 15 microns. If the width D5 is greater than approximately 15 microns, the pore may have a weak or insufficient capillary force to enable the fluid 265 to flow into the porous surface 290 and to contribute to a turbulent flow of a fluid (e.g., the fluid 265) during convection heat transfer from the cooling interface region 260 (e.g., increase a Reynolds number of the fluid 265 to increase a convective heat transfer rate, among other examples). However, other values and ranges for the width D5 are within the scope of the present disclosure.

As shown in FIGS. 2A and 2B, an implementations of a device includes an IC die (e.g., the SoC IC die 210, among other examples) mounted to a substrate (e.g., the interposer 220, among other examples), where the IC die includes the cooling interface region 260 on a side facing away from the substrate. The cooling interface region 260 includes the channel region 275 and a row of pillar structures. The row of pillar structures includes the pillar structure 280 (e.g., a first pillar structure) extending approximately vertically to the height D1 (e.g., a first height) above a bottom of the channel region 275 and the pillar structure 285 (e.g., a second pillar structure) extending approximately vertically to the height D2 (e.g., a second height) above the bottom of the channel region 275, where the pillar structure 280 and the pillar structure 285 structure are separated by the channel region 275, and where the height D2 is lesser relative to the height D1.

FIG. 2C shows a side view of the fluid 265 flowing over the cooling interface region 260. The fluid 265 includes a laminar component 265a and a turbulent component 265b. Features of the cooling interface region 260 (e.g., the channel regions 270 and 275, the pillar structures 280 and 285, and/or the porous surfaces 290) may contribute to formation of the turbulent component 265b to increase a Reynolds number of the fluid 265 (and increase a rate of convective heat transfer from the SoC IC die 210 to the fluid 265).

In some the implementations, a portion of the fluid 265 flowing over the cooling interface region 260 encounters a phase change (e.g., a liquid phase to a vapor phase). In such implementations, heat transfer through the cooling interface region 260 may correspond to “two-phase cooling”.

FIG. 2D shows an isometric view of an example array of pillar structures and channel regions. As shown in FIG. 2D, the array of pillar structures includes a row of pillar structures (e.g., a first row of pillar structures) along a horizontal axis 295a (e.g., a first horizontal axis) and a row of pillar structures (e.g., a second row of pillar structures) along a horizontal axis 295b (e.g., a second horizontal axis) that is approximately parallel to the horizontal axis 295a. The channel region 275a (e.g., a first channel region) separates the pillar structure 280a and the pillar structure 285b. The pillar structure 280a extends to a height (e.g., a first height or the height D1, among other examples) that is greater relative to a height of the pillar structure 285b (e.g., a second height or the height D2, among other examples).

The row of pillar structures along the horizontal axis 295b includes the pillar structure 285b (e.g., a third pillar structure) and a pillar structure 280b (a fourth pillar structure). The pillar structure 285b extends to the height of the pillar structure 285a (e.g., the second height or the height D2, among other examples) and the pillar structure 280b extends to the height of the pillar structure 280a (e.g., the first height or the height D1, among other examples). In FIG. 2D, the pillar structure 280b is separated from the pillar structure 285b by the channel region 275a.

Further, and shown in FIG. 2D, the pillar structure 285a is separated from the pillar structure 280b by the channel region 275b (e.g. a second channel region) that is approximately orthogonal to the channel region 275a. Additionally, or alternatively, the pillar structure 285b is separated from the pillar structure 280a by the channel region 275b.

A relative orientation of one or more channel regions (e.g., a relative orientation of the channel region 275a to the channel region 275b, among other examples) may be approximately orthogonal (e.g., approximately 90 degrees). Additionally, or alternatively, the relative orientation may be included in a range of approximately 75 degrees to approximately 105 degrees. However, other configurations, values, and ranges for the relative orientation are within the scope of the present disclosure.

As described in connection with FIGS. 2A and 2D and elsewhere herein, an implementation of the semiconductor die package 205 includes an integrated circuit die (e.g., the SoC IC die 210, among other examples) having the cooling interface region 260 in a first side. The cooling interface region 260 includes, in a top-down view of the integrated circuit die, an array of at least two columns and at least two rows of pillar structures (e.g., the pillar structures 280a, 280b, 285a, 285b) separated by channel regions (e.g., the channel regions 275a and 275b), where the array is configured to transfer heat from the integrated circuit die to a fluid (e.g., the fluid 265) using thermal convection. The semiconductor die package 205 includes one or more connection structures 230 connected to a second side of the integrated circuit die that is opposite the first side, where the one or more connection structures 230 are configured to conduct heat from the integrated circuit die to a substrate (e.g., the interposer 220, among other examples) below integrated circuit die using thermal conduction.

The number and arrangement of features of the semiconductor die package 205 including the cooling interface region 260 in FIGS. 2A-2D are provided as one or more examples. In practice, there may be additional features, different features, or differently arranged features than those shown in FIGS. 2A-2D.

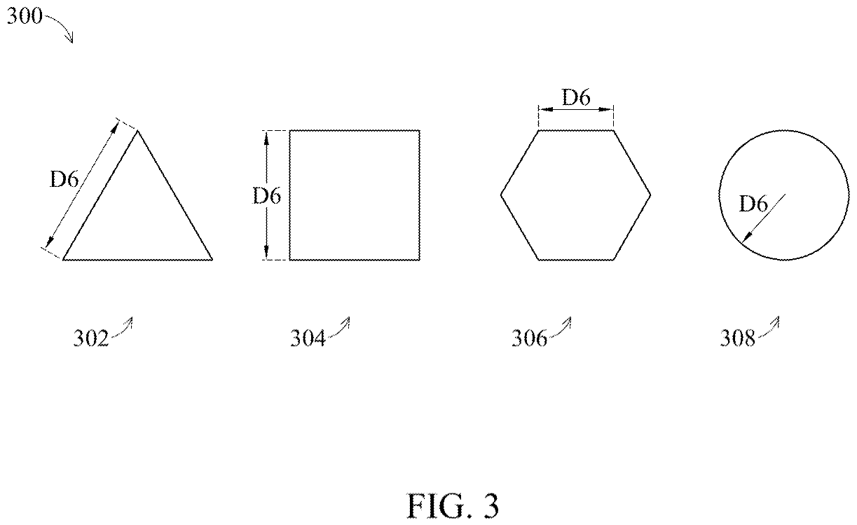

FIG. 3 is a diagram of example implementations 300 of pillars included in the cooling interface region 260 described herein. FIG. 3 illustrates a top-down view of a pillar structure (e.g., the pillar structure 280 and/or the pillar structure 285 of FIG. 2B, among other examples).

As shown in example 302, a shape of a top-down view of a pillar structure corresponds to a triangular shape. The triangular shape may correspond to an isosceles triangle having a characteristic dimension D6. In some implementations, the characteristic dimension D6 corresponds to the width D4 as described in connection with FIG. 2B. In some implementations, the characteristic dimension D6 corresponds to the width D3 as described in connection with FIG. 2B. However, other values and ranges for the characteristic dimension D6 are within the scope of the present disclosure.

As shown in example 304, a shape of a top-down view of a pillar structure corresponds to a rectangular shape. The rectangular shape may include at least one side having the characteristic dimension D6.

As shown in example 306, a shape of a top-down view of a pillar structure corresponds to a hexagonal shape. The hexagonal shape may include at least one side having the characteristic dimension D6.

As shown in example 308, a shape of a top-down view of a pillar structure corresponds to a circular shape. The circular shape may have a radius having the characteristic dimension D6.

As indicated above, FIG. 3 is provided as an example. Other examples and shapes of a pillar structure may differ from what is described with regard to FIG. 3.

FIGS. 4A-4J are diagrams of an example manufacturing process 400 used to fabricate the cooling interface region 260 described herein. The manufacturing process 400 may be performed by one or more tools of the manufacturing tool sets 105-150 as described in connection with FIG. 1. Additionally and/or alternatively, the manufacturing process 400 may be performed in a frontend semiconductor manufacturing facility (e.g., a wafer/die processing facility) that includes frontend semiconductor processing tools such as photolithography tools, developer tools, photoresist tools, and/or other wafer/die processing tools, which may enable more precise processing relative to the use of backend/packaging processing tools.

As shown in FIG. 4A, and as part of an operation 402, a layer of a photoresist material 404 is formed on a backside surface of the SoC IC die 210. For example, the photoresist tool of the RDL tool set 105 (or a spin coating tool in a frontend semiconductor manufacturing facility) may deposit (e.g., spin coat, among other examples) the layer of photoresist material 404 on the backside surface of the SoC IC die 210.

As shown in FIG. 4B, and as part of an operation 406, a pattern 408 may be formed in the layer of photoresist material 404. For example, the photolithography exposure tool of the RDL tool set 105 (or a photolithography tool in a frontend semiconductor manufacturing facility) may expose portions of the layer of the photoresist material 404 to radiation (e.g., extreme ultraviolet light, among other examples) and the photoresist develop tool (or a developer tool in a frontend semiconductor manufacturing facility) may develop and remove the portions to form the pattern 408.

As shown in FIG. 4C, and as part of an operation 410, material may be removed from the SoC IC die 210 to form one or more recesses 412 in the SoC IC die 210. For example, the etch tool of the RDL tool set 105 (or an etch tool in a frontend semiconductor manufacturing facility) may remove the material based on the pattern 408 using a plasma based etch technique, a dry-etch based technique or a wet-etch based technique, among other examples.

As shown in FIG. 4D, and as part of an operation 414, the layer of photoresist material 404 may be removed. For example, the photoresist ashing tool of the RDL tool set 105 (or a photoresist removal tool in a frontend semiconductor manufacturing facility) may remove the layer of photoresist material 404.

As shown in FIG. 4E, and as part of an operation 416, a layer of photoresist material 418 may be formed on the backside surface of the SoC IC die 210 (and in the one or more recesses 412). For example, the photoresist tool of the RDL tool set 105 (or a spin coating tool in a frontend semiconductor manufacturing facility) may deposit (e.g., spin coat, among other examples) the layer of photoresist material 418 on the backside surface of the SoC IC die 210 (and in the one or more recesses 412).

As shown in FIG. 4F, and as part of an operation 420, a pattern 422 may be formed in the layer of photoresist material 418. For example, the photolithography exposure tool of the RDL tool set 105 (or a photolithography exposure tool in a frontend semiconductor manufacturing facility) may expose portions of the layer of the photoresist material 418 to radiation (e.g., extreme ultraviolet light, among other examples) and the photoresist develop tool (or a developer tool in a frontend semiconductor manufacturing facility) may develop and remove the portions to form the pattern 422.

As shown in FIG. 4G, and as part of an operation 424, material may be removed from the SoC IC die 210 to form one or more recesses 426 in the SoC IC die 210. For example, the etch tool of the RDL tool set 105 (or an etch tool in a frontend semiconductor manufacturing facility) may remove the material based on the pattern 422 using a plasma based etch technique, a dry-etch based technique or a wet-etch based technique, among other examples.

As shown in FIG. 4H, and as part of an operation 428, the layer of photoresist material 418 may be removed. For example, the photoresist ashing tool of the RDL tool set 105 (or a photoresist removal tool in a frontend semiconductor manufacturing facility) may remove the layer of photoresist material 418. As shown in FIG. 4H, the channel region 270, the channel region 275, the pillar structure 280, and the pillar structure 285 have been formed concurrently.

As shown in FIG. 4I, and as part of an operation 430, surfaces of the cooling interface region 260 may be treated to form the porous surface 290. As an example and as part of treating the surfaces of the cooling interface region 260, the etch tool of the RDL tool set 105 (or an etch tool in a frontend semiconductor manufacturing facility) may use an etching operation to create pores using a plasma based etch technique, a dry-etch based technique or a wet-etch based technique, among other examples. In some implementations, the surface of the cooling interface region 260 is laterally etched to form the porous surface 290.

In some implementations, the surfaces of the cooling interface region 260 may be treated through the deposition tool of the RDL tool set 105 depositing a layer of a metal material (e.g., approximately 20 microns to approximately 300 microns thick, among other examples) on surfaces of the cooling interface region 260 and the etch tool of the RDL tool set 105 etching the layer of metal material. Additionally, or alternatively, a mechanical operation by the dicing tool or the sawing tool of the singulation tool set 125 may treat surfaces (e.g., roughen surfaces) of the cooling interface region 260 to from one or more portions of the porous surface 290.

As shown in FIG. 4J, and as part of an operation 432, integrated circuitry 434 is formed on a frontside surface of the SoC IC die 210. In some implementations, one or more portions of integrated circuitry 434 are formed using photolithography tools, etch tools, and deposition tools included in the RDL tool set 105 and/or using photolithography tools, developer tools, photoresist tools, and/or other wafer/die processing tools in a frontend semiconductor manufacturing facility. In some implementations, one or more portions of integrated circuitry 434 are formed using other photolithography tools, other etch tools, and other deposition tools excluded from the RDL tool set 105. The integrated circuitry 434 may be formed prior to, during, and/or after the formation of the cooling interface region 260.

The manufacturing process 400 may include variations and/or permutations. For example, the manufacturing process 400 may include laser ablation process to form one or more portions of the channel region 270, the channel region 275, the pillar structure 280, and the pillar structure 285. Additionally, or alternatively, a layer of a hard masking material may be used in contrast to the layer of photoresist material 404 and/or the layer of photoresist material 418. Additionally, or alternatively, the integrated circuitry 434 may be formed prior to formation of the cooling interface region 260. Additionally, or alternatively, temporary carriers may be used for carrying/processing the SoC IC die 210 during formation of the cooling interface region 260. Additionally, or alternatively and using similar techniques, the cooling interface region 260 may be formed in a mold compound surrounding or encapsulating the SoC IC die 210 (e.g., the mold compound 235 of FIG. 2A) as opposed to the backside surface of the SoC IC die 210.

The manufacturing process 400 may be extended to include encapsulating the SoC IC die 210 as part of a semiconductor die package (e.g., the semiconductor die package 205 of FIG. 2A, among other examples) Additionally, or alternatively, the manufacturing process 400 may be extended to include mounting the SoC IC die 210 to an interface board of a computing system, where the cooling interface region 260 is exposed to a fluid (e.g., the fluid 265 of FIGS. 2B and 2C, among other examples) within the computing system.

The number and arrangement of operations in FIGS. 4A-4J are provided as one or more examples. In practice, there may be additional operations, different operations, or differently arranged operations than those shown in FIGS. 4A-4J.

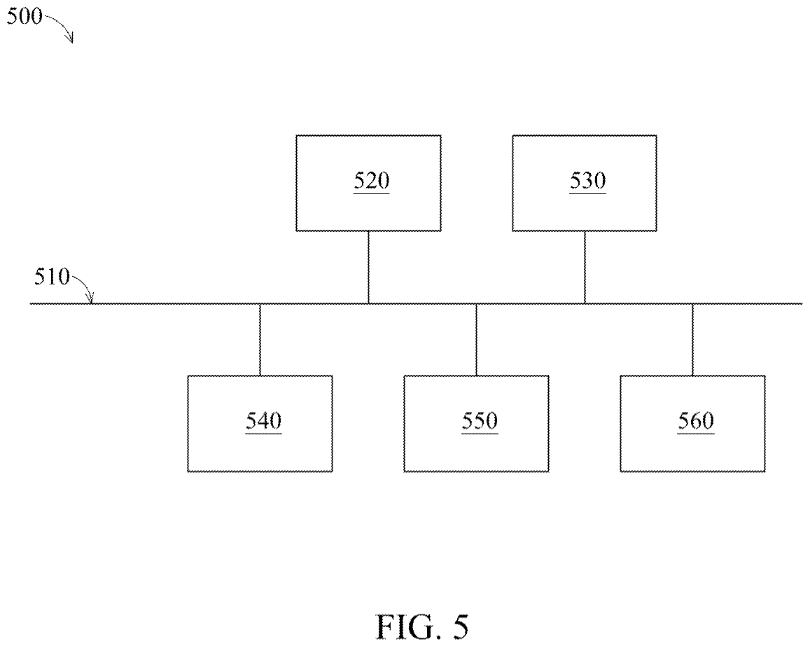

FIG. 5 is a diagram of example components of a device 500 associated with fabricating a cooling interface region (e.g., the cooling interface region 260) for a semiconductor die package (e.g., the semiconductor die package 205, among other examples). Device 500 may correspond to one or one or more of the semiconductor processing tool sets 105-150 described in connection with FIG. 1. In some implementations, one or more of the semiconductor processing tool sets 105-150 may include one or more devices 500 and/or one or more components of device 500. As shown in FIG. 5, device 500 may include a bus 510, a processor 520, a memory 530, an input component 540, an output component 550, and a communication component 560.

Bus 510 may include one or more components that enable wired and/or wireless communication among the components of device 500. Bus 510 may couple together two or more components of FIG. 5, such as via operative coupling, communicative coupling, electronic coupling, and/or electric coupling. Processor 520 may include a central processing unit, a graphics processing unit, a microprocessor, a controller, a microcontroller, a digital signal processor, a field-programmable gate array, an application-specific integrated circuit, and/or another type of processing component. Processor 520 is implemented in hardware, firmware, or a combination of hardware and software. In some implementations, processor 520 may include one or more processors capable of being programmed to perform one or more operations or processes described elsewhere herein.

Memory 530 may include volatile and/or nonvolatile memory. For example, memory 530 may include random access memory (RAM), read only memory (ROM), a hard disk drive, and/or another type of memory (e.g., a flash memory, a magnetic memory, and/or an optical memory). Memory 530 may include internal memory (e.g., RAM, ROM, or a hard disk drive) and/or removable memory (e.g., removable via a universal serial bus connection). Memory 530 may be a non-transitory computer-readable medium. Memory 530 stores information, instructions, and/or software (e.g., one or more software applications) related to the operation of device 500. In some implementations, memory 530 may include one or more memories that are coupled to one or more processors (e.g., processor 520), such as via bus 510.

Input component 540 enables device 500 to receive input, such as user input and/or sensed input. For example, input component 540 may include a touch screen, a keyboard, a keypad, a mouse, a button, a microphone, a switch, a sensor, a global positioning system sensor, an accelerometer, a gyroscope, and/or an actuator. Output component 550 enables device 500 to provide output, such as via a display, a speaker, and/or a light-emitting diode. Communication component 560 enables device 500 to communicate with other devices via a wired connection and/or a wireless connection. For example, communication component 560 may include a receiver, a transmitter, a transceiver, a modem, a network interface card, and/or an antenna.

Device 500 may perform one or more operations or processes described herein. For example, a non-transitory computer-readable medium (e.g., memory 530) may store a set of instructions (e.g., one or more instructions or code) for execution by processor 520. Processor 520 may execute the set of instructions to perform one or more operations or processes described herein. In some implementations, execution of the set of instructions, by one or more processors 520, causes the one or more processors 520 and/or the device 500 to perform one or more operations or processes described herein. In some implementations, hardwired circuitry is used instead of or in combination with the instructions to perform one or more operations or processes described herein. Additionally, or alternatively, processor 520 may be configured to perform one or more operations or processes described herein. Thus, implementations described herein are not limited to any specific combination of hardware circuitry and software.

The number and arrangement of components shown in FIG. 5 are provided as an example. Device 500 may include additional components, fewer components, different components, or differently arranged components than those shown in FIG. 5. Additionally, or alternatively, a set of components (e.g., one or more components) of device 500 may perform one or more functions described as being performed by another set of components of device 500.

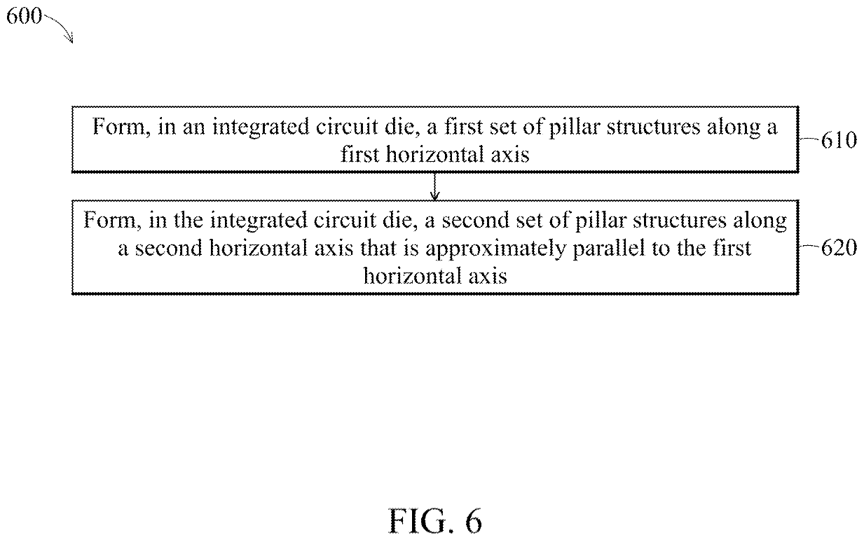

FIG. 6 is a flowchart of an example process 600 associated FIG. 6 is a flowchart of an example process 600 associated with manufacturing the semiconductor die package 205 including the cooling interface region 260 described herein. In some implementations, one or more process blocks of FIG. 6 are performed by one or more of the semiconductor processing tool sets 105-150 described in connection with FIG. 1 Additionally and/or alternatively, one or more process blocks of FIG. 6 are performed by one or more semiconductor processing tools in a frontend semiconductor manufacturing facility. Additionally, or alternatively, one or more process blocks of FIG. 6 may be performed by one or more components of device 500, such as processor 520, memory 530, input component 540, output component 550, and/or communication component 560.

As shown in FIG. 6, process 600 may include forming, in an integrated circuit die, a first set of pillar structures along a first horizontal axis. (block 610). For example, one or more semiconductor processing tools (e.g., one or more of the semiconductor processing tool sets 105-150 such as photolithography tools and the etch tool of the RDL tool set 105, photolithography tools and the etch tool of the frontend semiconductor manufacturing facility) may form, in an integrated circuit die (e.g., the SoC IC die 210, among other examples), a first set of pillar structures along a first horizontal axis (e.g., the horizontal axis 295a), as described above. In some implementations, the first set of pillar structures includes, in a top-down view of the integrated circuit die, a first pillar structure (e.g., the pillar structure 280a) and a second pillar structure (e.g., the pillar structure 285a) separated by a channel region 275a. In some implementations, the first pillar structure extends to a first height (e.g., the height D1) above a bottom of the channel region 275a. In some implementations, the second pillar structure extends to a second height (e.g., the height D2) above the bottom of the channel region 275a.

As further shown in FIG. 6, process 600 may include forming, in the integrated circuit die, a second set of pillar structures along a second horizontal axis that is approximately parallel to the first horizontal axis (block 620). For example, one or more semiconductor processing tools (e.g., one or more of the semiconductor processing tool sets 105-150 such as photolithography tools and the etch tool of the RDL tool set 105, photolithography tools and the etch tool of the frontend semiconductor manufacturing facility) may form, in the integrated circuit die, a second set of pillar structures along a second horizontal axis (e.g., the horizontal axis 295b) that is approximately parallel to the first horizontal axis, as described above. In some implementations, the second set of pillar structures includes, in the top-down view of the integrated circuit die, a third pillar structure (e.g., the pillar structure 280b) and a fourth pillar structure (e.g., the pillar structure 285b) separated by the channel region 275a. In some implementations, the third pillar structure extends to the first height above the bottom of the channel region 275a. In some implementations, the fourth pillar structure extends to the second height above the bottom of the channel region.

Process 600 may include additional implementations, such as any single implementation or any combination of implementations described below and/or in connection with one or more other processes described elsewhere herein.

In a first implementation, forming the first set of pillar structures along the first horizontal axis (e.g., the horizontal axis 295a) and forming the second set of pillar structures along the second horizontal axis (e.g., the horizontal axis 295b) includes concurrently forming the first set of pillar structures (e.g., the pillar structures 280a and 285a) and the second set of pillar structures (e.g., the pillar structures 280b and 285b) using an etching technique, where the etching technique further forms the channel region 275a.

In a second implementation, alone or in combination with the first implementation, forming the first set of pillar structures (e.g., the pillar structures 280a and 285a) along the first horizontal axis (e.g., the horizontal axis 295a) and forming the second set of pillar structures (e.g., the pillar structures 280b and 285b) along the second horizontal axis (e.g., the horizontal axis 295b) includes forming the first set of pillar structures and the second set of pillar structures using a laser ablation technique, where the laser ablation technique further forms the channel region.

In a third implementation, alone or in combination with one or more of the first and second implementations, process 600 includes forming integrated circuitry 434 of the integrated circuit die (e.g., the SoC IC die 210, among other examples) prior to forming the first set of pillar structures (e.g., the pillar structures 280a and 285a) and the second set of pillar structures (e.g., the pillar structures 280b and 285b).

In a fourth implementation, alone or in combination with one or more of the first through third implementations, process 600 includes forming integrated circuitry 434 of the integrated circuit die (e.g., the SoC IC die 210, among other examples) subsequent to forming the first set of pillar structures (e.g., the pillar structures 280a and 285a) and the second set of pillar structures (e.g., the pillar structures 280b and 285b).

In a fifth implementation, alone or in combination with one or more of the first through fourth implementations, process 600 includes mounting the integrated circuit die (e.g., the SoC IC die 210) to an interface board of a computing system, where mounting the integrated circuit die to the interface board exposes surfaces of the first set of pillar structures (e.g., the pillar structures 280a and 285a) and the second set of pillar structures (e.g., the pillar structures 280b and 285b) to a fluid (e.g., the fluid 265) within the computing system.

In a sixth implementation, alone or in combination with one or more of the first through fifth implementations, process 600 includes treating surfaces of the first set of pillar structures (e.g., the pillar structures 280a and 285a), the second set of pillar structures (e.g., the pillar structures 280b and 285b), and the channel regions (e.g., the channel regions 275a and 275b) to create porous surfaces (e.g., the porous surface 290) on the first set of pillar structures, the second set of pillar structures, and the channel regions.

In a seventh implementation, alone or in combination with one or more of the first through sixth implementations, treating the surfaces includes depositing a layer of material on the surfaces, and etching the layer of material.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

Some implementations described herein include systems and techniques for fabricating a semiconductor die package that includes a cooling interface region formed in surface of an integrated circuit die. The cooling interface region, which includes a combination of channel regions and pillar structures, may be directly exposed to a fluid above and/or around the semiconductor die package.

In this way, the cooling interface region causes a turbulent flow of the fluid to increase a rate of convective heat transfer from the semiconductor die package relative to a semiconductor package not including the cooling interface region. Additionally, a thickness of the semiconductor die package may be reduced relative to another semiconductor die package including a thermal interface material, a heat spreader component, and/or a lid component, thereby saving space in a computing system. Additionally, the semiconductor die package including the cooling interface region may increase the efficiency of the fabrication facility relative to another fabrication facility that fabricates the semiconductor die package including the thermal interface material, the heat spreader component, and/or the lid component.

As described in greater detail above, some implementations described herein provide a device. The device includes a substrate. The device includes an integrated circuit die mounted to the substrate and having a cooling interface region on a side facing away from the substrate. The cooling interface region includes a channel region and a row of pillar structures. The row of pillar structures includes a first pillar structure extending approximately vertically to a first height above a bottom of the channel region and a second pillar structure extending approximately vertically to a second height above the bottom of the channel region, where the first pillar structure and the second pillar structure are separated by the channel region, and where the second height is lesser relative to the first height.

As described in greater detail above, some implementations described herein provide a semiconductor die package. The semiconductor die package includes an integrated circuit die having a cooling interface region in a first side. The cooling interface region includes, in a top-down view of the integrated circuit die, an array of at least two columns and at least two rows of pillar structures separated by channel regions, where the array is configured to transfer heat from the integrated circuit die to a fluid using thermal convection. The semiconductor die package includes one or more connection structures connected to a second side of the integrated circuit die that is opposite the first side, where the one or more connection structure are configured to conduct heat from the integrated circuit die to a substrate below integrated circuit die using thermal conduction.

As described in greater detail above, some implementations described herein provide a method. The method includes forming, in an integrated circuit die, a first set of pillar structures along a first horizontal axis, where the first set of pillar structures includes, in a top-down view of the integrated circuit die, a first pillar structure and a second pillar structure separated by a channel region, where the first pillar structure extends to a first height above a bottom of the channel region, and where the second pillar structure extends to a second height above the bottom of the channel region. The method includes forming, in the integrated circuit die, a second set of pillar structures along a second horizontal axis that is approximately parallel to the first horizontal axis, where the second set of pillar structures includes, in the top-down view of the integrated circuit die, a third pillar structure and a fourth pillar structure separated by the channel region, where the third pillar structure extends to the first height above the bottom of the channel region, and where the fourth pillar structure extends to the second height above the bottom of the channel region.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate; and
an integrated circuit die mounted to the substrate and having a cooling interface region on a side facing away from the substrate comprising:
a channel region; and
a row of pillar structures comprising:
a first pillar structure extending approximately vertically to a first height above a bottom of the channel region; and
a second pillar structure extending approximately vertically to a second height above the bottom of the channel region,
wherein the first pillar structure and the second pillar structure are separated by the channel region, and
wherein the second height is lesser relative to the first height.

2. The device of claim 1, wherein a shape of a top-down view of the first pillar structure or the second pillar structure corresponds to:
a triangular shape,
a rectangular shape,
a hexagonal shape, or
a circular shape.

3. The device of claim 1, wherein the first pillar structure, the second pillar structure, and/or the channel region comprise porous surfaces.

4. The device of claim 3, wherein a width of a pore included in the porous surfaces is included in a range of greater than 0 microns to less than approximately 15 microns.

5. The device of claim 1, wherein the channel region corresponds to a first channel region that is adjacent to a first side of the first pillar structure and further comprising:
a second channel region adjacent to a second side of the first pillar structure that is opposite the first side of the first pillar structure,
wherein a width of the second channel region is greater relative to a width of the first channel region.

6. The device of claim 5, wherein a ratio of the width of the second channel region to the width of the first channel region is greater than approximately 3:2.

7. The device of claim 1, wherein the row of pillar structures corresponds to a first row of pillar structures along a first horizontal axis, the channel region corresponds to a first channel region, and further comprising:
a second row of pillar structures along a second horizontal axis that is approximately parallel to the first horizontal axis,
wherein the second row of pillar structures comprises:
height,
a third pillar structure extending approximately vertically to the second wherein the third pillar structure is separated from first pillar structure by a second channel region that is approximately orthogonal to the first channel region; and
a fourth pillar structure extending approximately vertically to the first height,
wherein the fourth pillar structure is separated from the second pillar structure by the second channel region that is approximately orthogonal to the first channel region, and
wherein the third pillar structure and the fourth pillar structure are separated by the first channel region.

8. The device of claim 7, wherein a width of the first channel region is greater than approximately 10 microns.

9. A semiconductor die package, comprising;
an integrated circuit die having a cooling interface region in a first side and comprising, in a top-down view of the integrated circuit die, an array of at least two columns and at least two rows of pillar structures separated by channel regions,
wherein the array is configured to transfer heat from the integrated circuit die to a fluid using thermal convection; and
one or more connection structures connected to a second side of the integrated circuit die that is opposite the first side,
wherein the one or more connection structure are configured to conduct heat from the integrated circuit die to a substrate below integrated circuit die using thermal conduction.

10. The semiconductor die package of claim 9, wherein at least one first pillar structure, of the at least two rows of pillar structures, includes a first height; and
wherein at least one second pillar structure, of the at least two rows of pillar structures, includes a second height that is lesser relative to the first height.

11. The semiconductor die package of claim 9, wherein at least one first channel region, of the channel regions, includes a first width; and
wherein at least one second channel region, of the channel regions, includes a second width that is lesser relative to the first width.

12. The semiconductor die package of claim 9, wherein the array of at least two columns and the at least two rows of the pillar structures and the channel regions comprise:
porous surfaces configured to increase a Reynolds number of the fluid,
wherein the porous surfaces are configured to be directly exposed to the fluid without an intervening thermal interface material, without an intervening heat spreader component, and without an intervening lid component.

13. A method, comprising:
forming, in an integrated circuit die, a first set of pillar structures along a first horizontal axis,
wherein the first set of pillar structures comprises, in a top-down view of the integrated circuit die, a first pillar structure and a second pillar structure separated by a channel region,
wherein the first pillar structure extends to a first height above a bottom of the channel region, and
wherein the second pillar structure extends to a second height above the bottom of the channel region; and
forming, in the integrated circuit die, a second set of pillar structures along a second horizontal axis that is approximately parallel to the first horizontal axis,
wherein the second set of pillar structures comprises, in the top-down view of the integrated circuit die, a third pillar structure and a fourth pillar structure separated by the channel region,
wherein the third pillar structure extends to the first height above the bottom of the channel region, and
wherein the fourth pillar structure extends to the second height above the bottom of the channel region.

14. The method of claim 13, wherein forming the first set of pillar structures along the first horizontal axis and forming the second set of pillar structures along the second horizontal axis comprises:
concurrently forming the first set of pillar structures and the second set of pillar structures using an etching technique,
wherein the etching technique further forms the channel region.

15. The method of claim 13, wherein forming the first set of pillar structures along the first horizontal axis and forming the second set of pillar structures along the second horizontal axis comprises:
forming the first set of pillar structures and the second set of pillar structures using a laser ablation technique,
wherein the laser ablation technique further forms the channel region.

16. The method of claim 13, further comprising:
forming integrated circuitry of the integrated circuit die prior to forming the first set of pillar structures and the second set of pillar structures.

17. The method of claim 13, further comprising:
forming integrated circuitry of the integrated circuit die subsequent to forming the first set of pillar structures and the second set of pillar structures.

18. The method of claim 13, further comprising:
mounting the integrated circuit die to an interface board of a computing system,
wherein mounting the integrated circuit die to the interface board exposes surfaces of the first set of pillar structures and the second set of pillar structures to a fluid within the computing system.

19. The method of claim 13, further comprising:
treating surfaces of the first set of pillar structures, the second set of pillar structures, and the channel regions to create porous surfaces on the first set of pillar structures, the second set of pillar structures, and the channel regions.

20. The method of claim 19, wherein treating the surfaces comprises:
depositing a layer of material on the surfaces, and
etching the layer of material.
